(19) United States
(12) Patent Application Publication
(10) Pub. No.: US 2024/0070372 A1
(43) Pub. Date: Feb. 29, 2024

(54) QUANTUM LAYOUT OPTIMIZATION METHOD, APPARATUS, AND COMPUTER-READABLE STORAGE MEDIUM

(71) Applicant: Alibaba Damo (Hangzhou) Technology Co., Ltd., Hangzhou (CN)

(72) Inventors: Tian XIA, Hangzhou (CN); Feng WU, Hangzhou (CN); Jianjun CHEN, Hangzhou (CN); Xiaotong NI, Hangzhou (CN); Qi YE, Beijing (CN); Huihai ZHAO, Beijing (CN)

(21) Appl. No.: 18/351,864

(22) Filed: Jul. 13, 2023

(30) Foreign Application Priority Data
Aug. 16, 2022 (CN) 202210978086.X

(51) Int. Cl. G06F 30/398; G06F 30/392; G06N 10/20

(52) U.S. Cl. CPC G06F 30/398; G06F 30/392; G06N 10/20

(57) ABSTRACT

A quantum layout optimization method includes: determining target Hamiltonian parameters of a quantum device; determining an initial quantum layout of the quantum device and initial geometric parameters of the initial quantum layout; determining a target gradient of Hamiltonian parameters of the quantum device to geometric parameters of the initial quantum layout; and adjusting the initial geometric parameters based on the target gradient to have the Hamiltonian parameters of the quantum device be the target Hamiltonian parameters to obtain a target quantum layout.

### CROSS-REFERENCE TO RELATED APPLICATIONS

The disclosure claims the benefits of priority to Chinese Application No. 202210978086.X, filed on Aug. 16, 2022, which is incorporated herein by reference in its entirety.

### TECHNICAL FIELD

The present disclosure relates to the field of superconducting quantum, and more particularly to a method, an apparatus, and a computer-readable storage medium for quantum layout optimization.

### BACKGROUND

Generally, electromagnetic simulation is needed for adjusting the parameters of a quantum layout. For every time the parameters are adjusted, the electromagnetic simulation is required. Hamiltonian parameters of a quantum model corresponding to the layout is calculated, then the geometric parameters of the quantum layout are adjusted according to a change of the Hamiltonian parameters. The process needs to be iterated until the layout design requirements are met.

Therefore, the operations are complicate and efficiency is low during adjusting the parameters of the quantum layout.

### SUMMARY OF THE DISCLOSURE

Embodiments of the present disclosure provide a quantum layout optimization method. The quantum layout optimization method includes: determining target Hamiltonian parameters of a quantum device; determining an initial quantum layout of the quantum device and initial geometric parameters of the initial quantum layout; determining a target gradient of Hamiltonian parameters of the quantum device to geometric parameters of the initial quantum layout; and adjusting the initial geometric parameters based on the target gradient to have the Hamiltonian parameters of the quantum device being the target Hamiltonian parameters to obtain a target quantum layout.

Embodiments of the present disclosure provide an apparatus for quantum layout optimization. The apparatus includes a memory configured to store instructions; and one or more processors configured to execute the instructions to cause the apparatus to perform: determining target Hamiltonian parameters of a quantum device; determining an initial quantum layout of the quantum device and initial geometric parameters of the initial quantum layout; determining a target gradient of Hamiltonian parameters of the quantum device to geometric parameters of the initial quantum layout; and adjusting the initial geometric parameters based on the target gradient to have the Hamiltonian parameters of the quantum device being the target Hamiltonian parameters to obtain a target quantum layout.

Embodiments of the present disclosure provide a non-transitory computer readable medium that stores a set of instructions that is executable by one or more processors of an apparatus to cause the apparatus to perform operations including: determining target Hamiltonian parameters of a quantum device; determining an initial quantum layout of the quantum device and initial geometric parameters of the initial quantum layout; determining a target gradient of Hamiltonian parameters of the quantum device to geometric parameters of the initial quantum layout; and adjusting the initial geometric parameters based on the target gradient to have the Hamiltonian parameters of the quantum device being the target Hamiltonian parameters to obtain a target quantum layout.

### BRIEF DESCRIPTION OF THE DRAWINGS

Embodiments and various aspects of the present disclosure are illustrated in the following detailed description and the accompanying figures. Various features shown in the figures are not drawn to scale.

FIG. 1 shows a hardware structure block diagram of an exemplary computer terminal for realizing a quantum layout optimization method.

FIG. 2 is a flow chart of a first exemplary quantum layout optimization method, according to some embodiments of the present disclosure.

FIG. 3 is a flow chart of a second exemplary quantum layout optimization method, according to some embodiments of the present disclosure.

FIG. 4 is a schematic diagram of an exemplary optimization process, according to some embodiments of the present disclosure.

FIG. 5 is a schematic diagram of another exemplary optimization process, according to some embodiments of the present disclosure.

FIG. 6 is a schematic diagram of another exemplary optimization process, according to some embodiments of the present disclosure.

FIG. 7 is a schematic diagram of an exemplary quantum bit pad, according to some embodiments of the present disclosure.

FIG. 8 is a schematic diagram of an exemplary mesh generation, according to some embodiments of the present disclosure.

FIG. 9 is a structural block diagram of a first exemplary quantum layout optimization device, according to some embodiments of the present disclosure.

FIG. 10 is a structural block diagram of a second exemplary quantum layout optimization device, according to some embodiments of the present disclosure.

FIG. 11 is a structural block diagram of an exemplary computer terminal, according to some embodiments of the present disclosure.

### DETAILED DESCRIPTION

Reference can now be made in detail to example embodiments, examples of which are illustrated in the accompanying drawings. The following description refers to the accompanying drawings in which the same numbers in different drawings represent the same or similar elements unless otherwise represented. The implementations set forth in the following description of example embodiments do not represent all implementations consistent with the disclosure. Instead, they are merely examples of apparatuses and methods consistent with aspects related to the disclosure as recited in the appended claims. Particular aspects of present disclosure are described in greater detail below. The terms and definitions provided herein control, if in conflict with terms and/or definitions incorporated by reference.

According to the embodiments of the present disclosure, a method for quantum layout optimization is provided. It should be noted that steps shown in a flow chart of the drawings may be executed in a computer system including, for example, a set of computer-executable instructions. Moreover, although a logic sequence is shown in the flow chart, the shown or described steps may be executed in a sequence different from the sequence herein under certain conditions.

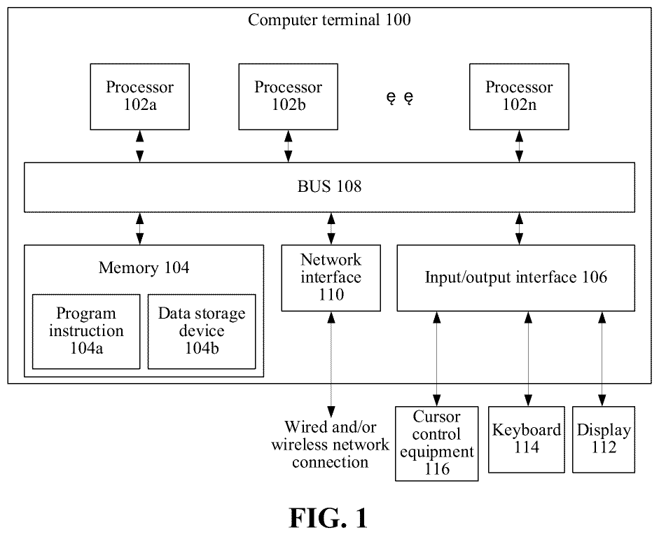

The method provided according to the present disclosure may be performed in a mobile terminal, a computer terminal, or a similar arithmetic device. FIG. 1 shows a hardware structure block diagram of an exemplary computer terminal (or a mobile device) for realizing a quantum layout optimization method. As shown in FIG. 1, a computer terminal 100 (or a mobile device) may include one or more processors (102a, 102b, . . . , 102n), a memory 104 for storing data, and a transmission device for a communication function. The processor may include, but is not limited to, a processing device such as a microprogrammed control unit (MCU) or a field programmable gate array (FPGA). In addition, computer terminal 100 may also include: a display, an input/output interface (I/O interface) 106, a universal serial BUS (USB) port (which may be included as one of ports of a BUS 108), a network interface 110, a display 112, a keyboard 114, a cursor control equipment 116, a power supply and/or a camera. A person of ordinary skill in the art may understand that the structure shown in FIG. 1 is only illustrative, and does not limit the structure of the above electronic device. For example, the computer terminal 100 may also include more or fewer components than those shown in FIG. 1, or has a configuration different from that shown in FIG. 1.

It should be noted that the above one or more processors and/or other data processing circuits may be generally referred to as “data processing circuit” herein. The data processing circuit may be fully or partially reflected as software, hardware, firmware or any other combination. In addition, the data processing circuit may be a single independent processing module, or be fully or partially incorporated into any one of other elements in the computer terminal 100 (or the mobile device). As involved in the embodiments of the present disclosure, the data processing circuit serves as a processor control (such as the selection of a variable resistance terminal path connected to the interface).

Memory 104 may be configured to store software programs and modules of application software, such as the program instructions 104a/data storage device 104b corresponding to the quantum layout optimization method. Processors (102a, 102b, . . . 102n) execute various functional applications and data processing by running the software programs and modules stored in memory 104, that is, a quantum layout optimization method of the above application programs is realized. Memory 104 may include a high-speed random memory, and may also include a non-volatile memory, for example, one or more magnetic storage devices, a flash memory, or another non-volatile solid-state memory. In some examples, the memory 104 may further include memories remotely disposed relative to the processor, and the remote memories may be connected to a computer terminal 100 through a network. Examples of the above network include, but are not limited to, the Internet, an intranet, a local area network, a mobile communication network, and a combination thereof.

The transmission device is configured to receive or send data via a network. An example of the above network may include a wireless network provided by a communication supplier of the computer terminal 100. In an example, the transmission device includes a network interface controller (NIC) which may be connected to other network devices through a base station to communicate with the Internet. In an example, the transmission device may be a radio frequency (RF) module, which communicates with the Internet in a wireless manner.

Display 112 may be, for example, a touch screen type liquid crystal display (LCD) that allows a user to interact with the user interface of the computer terminal 100 (or the mobile device).

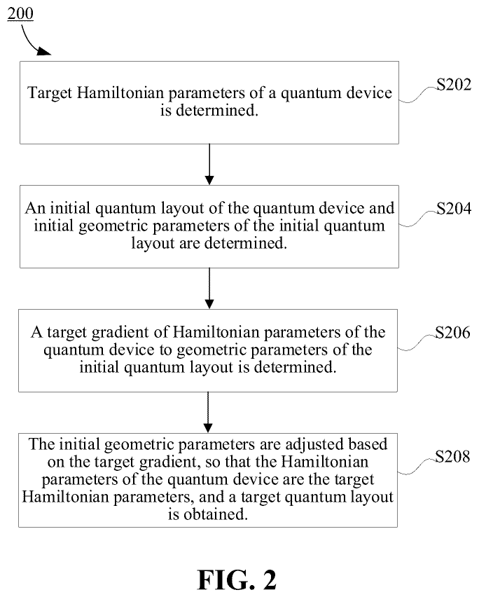

Under the above operating environment, the present disclosure provides a quantum layout optimization method as shown in FIG. 2. FIG. 2 is a flow chart of a quantum layout optimization method 200 according to some embodiments of the present disclosure. As shown in FIG. 2, method 200 includes the steps S202 to S208.

At step S202, target Hamiltonian parameters of a quantum device are determined.

A quantum bit layout corresponds to a circuit model, and the circuit model may be represented by a Hamiltonian. Circuit parameters are transformed into Hamiltonian parameters. The Hamiltonian parameters are target parameters of the quantum bit layout.

At step 204, an initial quantum layout of the quantum device and initial geometric parameters of the initial quantum layout are determined. Geometric parameters of a layout are the parameters describing a geometric shape of an element in a quantum bit layout.

At step 206, a target gradient of Hamiltonian parameters of the quantum device to geometric parameters of the initial quantum layout is determined.

When the geometric parameters change slightly, electromagnetic parameters will change, thus changing the circuit model corresponding to the quantum bit layout and the Hamiltonian parameters in the model. A ratio of a Hamiltonian parameter (target model parameter) change to the geometric parameter change is the gradient of the target model parameters to the geometric parameters. When the geometric parameters change slightly, the boundary of the geometric shape will change. The ratio of two changes (a geometric shape change/a geometric parameter change) is a gradient of the geometric shape boundary to the geometric parameters. When the geometric parameters change slightly, the boundary of the geometric shape and the mesh boundary will change, which leads to a change of solved electromagnetic parameters. The ratio of an electromagnetic parameter change to the geometric parameter change is a gradient of the electromagnetic parameters to the geometric parameters.

At step 208, the initial geometric parameters are adjusted based on the target gradient, so that the Hamiltonian parameters of the quantum device are the target Hamiltonian parameters, and a target quantum layout is obtained.

Through the above steps, the target gradient of the Hamiltonian parameters of the quantum device to the geometric parameters of the initial quantum layout is determined. As the target gradient reflects a change rule of the Hamiltonian parameters of the quantum device with the geometric parameters, the initial geometric parameters of the quantum device may be adjusted based on the change rule to obtain the target quantum layout corresponding to the target Hamiltonian parameters. Compared with the method using the electromagnetic simulation, a method of determining a change direction of the Hamiltonian parameters relative to the initial geometric parameters based on the target gradient can avoid invalid adjustment effectively, so that the adjustment of the geometric parameters is effective, the quantum layout optimization efficiency is greatly improved, and then the technical problems of complicated operation and low efficiency during adjusting the parameters of the quantum layout are solved.

It should be noted that the geometric parameters in the embodiments of the present disclosure may be used for describing the quantum layout and the quantum device in the quantum layout, for example, may be used for describing the length and width of a rectangular shape, the radius and the center position of a circle shape, etc. A quantum layout, also referred as a superconducting quantum chip, is a design drawing of the superconducting quantum chip, which is the result of a quantum chip design stage and the starting point of quantum chip processing. A quantum energy level, electromagnetic field distribution and the like of superconducting quantum bits that need to be considered in the design stage are finally reflected in the layout. A process engineer performs lithography, deposition and other processing techniques according to the layout, and finally completes the quantum chip. A test engineer performs measurement activities according to the information provided by the layout. A quantum device in the superconducting quantum chip particularly refers to a superconducting quantum bit. The superconducting quantum bit forms a quantum circuit with the capacitor and inductor by using a quantum effect of the Josephson junctions. At extremely low temperatures, the circuit shows the quantum effect and satisfies the principle of superposition of quantum states and quantum measurement theory. Quantum state is a superposition of two states at the same time, which is the basic property of quantum computing. Physically, a quantum bit is a quantum state, and therefore, the quantum bit has the property of the quantum state. Due to a unique quantum property of the quantum state, the quantum bit has many characteristics different from a classical bit, which is one of the basic characteristics of quantum information science

In some embodiments, step S206 that determining a target gradient of Hamiltonian parameters of the quantum device to geometric parameters of the initial quantum layout includes: performing mesh division on the initial quantum layout of the quantum device to obtain a mesh boundary of the initial quantum layout; determining a first gradient of the mesh boundary to the geometric parameters of the initial quantum layout; determining a second gradient of the Hamiltonian parameters of the quantum device to the mesh boundary; and determining the target gradient of the Hamiltonian parameters of the quantum device to the geometric parameters of the initial quantum layout based on the first gradient and the second gradient. When the geometric parameters change slightly, the boundary of the geometric shape will change, and when mesh division is performed on the geometric shape, a boundary change of the geometric shape will correspond to a change of the mesh boundary. The ratio of a mesh boundary change to the geometric parameter change is the gradient of the mesh boundary to the geometric parameters.

After mesh division is performed on the initial quantum layout of the quantum device, the mesh boundary of the initial quantum layout is obtained. The change of the mesh boundary leads to a change of a matrix element of a solution system. The matrix element is the electromagnetic interaction between the ith mesh and the jth mesh. The change of the matrix element leads to a change of an unknown to be solved, for example, the number of division meshes, and the change of the unknown to be solved to the Hamiltonian is a gradient.

In some embodiments, the target gradient is determined based on a first gradient and a second gradient, where the first gradient is the gradient of the mesh boundary to the geometric parameters, and the second gradient is the gradient of the Hamiltonian parameters to the mesh boundary. Generally, it is impossible to determine how the Hamiltonian parameters of the quantum device change with the geometric parameters, that is, it is impossible to directly determine a change rule of Hamiltonian parameters relative to the geometric parameters, and then it is impossible to directly adjust the initial geometric parameters to have the Hamiltonian parameters of the quantum device as the target Hamiltonian parameters. In the embodiments provided by present disclosure, the gradient transfer based on the network boundary between the first gradient and the second gradient is equivalent to establishing the correlation between the Hamiltonian parameters and the geometric parameters, then the change rule of the Hamiltonian parameters relative to the geometric parameters may be determined, that is, the target gradient of the Hamiltonian parameters relative to the geometric parameters may be determined.

In some embodiments, the performing mesh division on the initial quantum layout of the quantum device to obtain a mesh boundary of the initial quantum layout includes: dividing the initial quantum layout based on a predetermined basic pattern to obtain a plurality of meshes of the predetermined basic pattern; and connecting vertices on the boundary of the initial quantum layout in the plurality of meshes into lines to obtain the mesh boundary of the initial quantum layout. When mesh division is performed, the mesh may be divided according to different shapes, for example, the mesh may be defined as triangle, rectangle, polygon and the like. When the initial quantum layout is divided, the smaller the predetermined basic pattern is, the finer the obtained division result is, that is, the corresponding mesh boundary tends to a real geometric shape.

It should be noted that when the initial quantum layout corresponding to the quantum device is divided, the mesh in the geometric middle of the initial quantum layout is basically unchanged by a change of shape, and only the mesh boundary after division is changed by a change of the geometric parameters. Therefore, in order to obtain the influence of the change of the geometric parameters on the change of the mesh boundary, a plurality of meshes obtained after mesh division is performed based on the predetermined basic pattern may be firstly determined, and then the mesh boundary is obtained based on the vertices of the meshes on the boundary. By adopting the above processing method, due to the relatively standard mesh division, the obtained mesh boundary is also relatively standard, which may also improve the accuracy of subsequent gradient calculation to a certain extent.

In some embodiments, the determining a first gradient of the mesh boundary to the geometric parameters of the initial quantum layout includes: determining a mesh boundary including a target number of meshes on the boundary obtained by dividing the initial quantum layout based on a predetermined basic pattern; and determining the first gradient of the mesh boundary to the geometric parameters of the initial quantum layout based on a change of the target number relative to the geometric parameters of the initial quantum layout. When the predetermined basic pattern is determined, the change of the geometric parameters may be directly reflected in the number of meshes included in the mesh boundary, that is, the first gradient of the mesh boundary to the geometric parameters of the initial quantum layout may be determined based on the change of the target number relative to the geometric parameters of the initial quantum layout. After the first gradient is determined in the above way, the first gradient may describe a change of the number of the target meshes relative to the geometric parameters of the initial quantum layout, that is to say, according to the first gradient, a change rule of the mesh boundary with the geometric parameters of the initial quantum layout may be directly determined, and on the other hand, the purpose of adjusting the geometric parameters of the quantum layout based on the mesh boundary may also be achieved.

In some embodiments, the following method may be used for determining a second gradient of the Hamiltonian parameters of the quantum device to the mesh boundary: performing electromagnetic simulation on the initial quantum layout of the quantum device to determine a change of the Hamiltonian parameters of the quantum device relative to a change of the mesh boundary; and determining the second gradient of the Hamiltonian parameters of the quantum device to the mesh boundary based on the change of the Hamiltonian parameters of the quantum device relative to the change of the mesh boundary. In this example, based on electromagnetic simulation, the second gradient of the Hamiltonian parameters of the quantum device to the mesh boundary may be calculated by determining the change of the Hamiltonian parameters of the quantum device relative to the change of the mesh boundary.

In some embodiments, the determining a target gradient of Hamiltonian parameters of the quantum device to geometric parameters of the initial quantum layout based on the first gradient and the second gradient includes: determining the Hamiltonian parameters of the quantum device with the geometric parameters of the initial quantum layout as variables by taking the mesh boundary as an intermediate transfer quantity in the first gradient and the second gradient; and determining the target gradient of the Hamiltonian parameters to the geometric parameters of the initial quantum layout. According to the above content, in the embodiments of the present disclosure, the gradient relationship between the “first gradient: the geometric parameters-the mesh boundary” and the “second gradient: the mesh boundary-the Hamiltonian parameters” may be obtained. Therefore, with the mesh boundary as an intermediate transfer quantity, the gradient relationship between the geometric parameters of the quantum layout and the Hamiltonian parameters of the quantum device, that is, the target gradient, may be established by using the gradient transfer of the first gradient and the second gradient. The target gradient may be used to directly adjust the geometric parameters of the quantum layout, thereby realizing to adjust the Hamiltonian parameters of the quantum device.

In some embodiments, step S208 that adjusting the initial geometric parameters based on the target gradient, so that the Hamiltonian parameters of the quantum device are the target Hamiltonian parameters, and a target quantum layout is obtained includes: determining an adjustment direction of the initial geometric parameters based on the target gradient; and adjusting the initial geometric parameters based on the adjustment direction multiple times, so that the Hamiltonian parameters of the quantum device are the target Hamiltonian parameters, and the target quantum layout is obtained.

In some embodiments, the quantum device may include multiple types of quantum bits, for example, a Fluxonium quantum bit. Other types of quantum bits may also be included, and no examples are given herein. Fluxonium is a type of superconducting quantum bit, composed of a Josephson junction parallel an inductor and a capacitor. A Fluxonium is generally made of an array of a large number (about 100) of Josephson junctions or high dynamic inductance materials. In this structure, an electric energy EC corresponding the capacitor, a magnetic energy EL corresponding to the inductor, and a Josephson energy EJ corresponding to the Josephson junction.

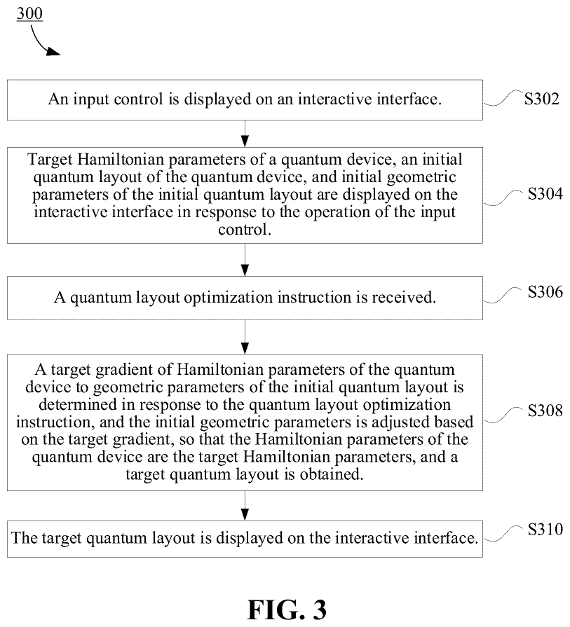

FIG. 3 is a flow chart of an exemplary quantum layout optimization method 300 according to some embodiment of the present disclosure. As shown in FIG. 3, method 300 includes steps S302 to S310.

At step S302, an input control is displayed on an interactive interface.

At step S304, target Hamiltonian parameters of a quantum device, an initial quantum layout of the quantum device, and initial geometric parameters of the initial quantum layout are displayed on the interactive interface in response to the operation of the input control.

At step S306, a quantum layout optimization instruction is received.

At step S308, a target gradient of Hamiltonian parameters of the quantum device to geometric parameters of the initial quantum layout is determined in response to the quantum layout optimization instruction, and the initial geometric parameters is adjusted based on the target gradient, so that the Hamiltonian parameters of the quantum device are the target Hamiltonian parameters, and a target quantum layout is obtained.

At step S310, the target quantum layout is displayed on the interactive interface.

Through the above steps, the user only needs to input the target Hamiltonian parameters, the initial quantum layout of the quantum device, and the initial geometric parameters of the initial quantum layout on the interactive interface, and the optimization of the quantum layout may be automatically completed. The target gradient of the Hamiltonian parameters of the quantum device to the geometric parameters of the initial quantum layout is determined. As the target gradient reflects a change rule of the Hamiltonian parameters of the quantum device with the geometric parameters, the initial geometric parameters of the quantum device may be adjusted based on the change rule to obtain the target quantum layout corresponding to the target Hamiltonian parameters. Compared with the method using the electromagnetic simulation, the method of determining a change direction of the Hamiltonian parameters relative to the initial geometric parameters based on the target gradient can avoid invalid adjustment directly and effectively, so that the adjustment of the geometric parameters is effective, the quantum layout optimization efficiency is greatly improved, and then the technical problems of complicated operation and low efficiency during adjusting the parameters of the quantum layout are solved.

Based on the above embodiments, the present disclosure further provides an optional implementation, which is described below.

Generally, when the layout of the quantum device is optimized by electromagnetic simulation, the process is a trial-and-error iterative process, which is troublesome and lacks directionality for arrangement and adjustment of the layout. The specific process is to draw a layout, then calculate the parameters of Hamiltonian, afterwards compare and optimize target requirements, and constantly modify the layout; and the whole process is numerically simulated, which is very slow.

The process of electromagnetic simulation of the layout including the quantum device is relatively complicated. It is necessary to perform mesh division (knowing which parts of the mesh will change when the geometric parameters on the layout change). Each mesh on the layout can be regarded as an unknown, corresponding to a dimension of an electromagnetic equation. When shapes in the layout change, for example, the length and width of a certain part increase, it is possible to determine which edges or points in the divided mesh change in which direction according to the change of the geometric parameters in the layout, and further an electromagnetic matrix equation is solved, thus obtaining gradient information of the electromagnetic parameters and the target model parameters to the geometric parameters in the layout.

It is difficult to obtain the gradient of each parameter to the geometric parameters directly, therefore, it is impossible to obtain the gradient of the Hamiltonian parameters to the geometric parameters directly, and it is impossible to perform one step optimization for the layout design according to the target Hamiltonian parameters.

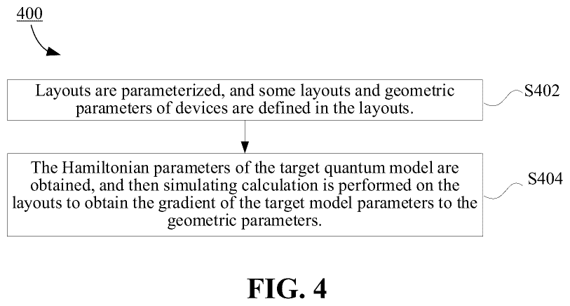

In the embodiments of the present disclosure, in order to solve a gradient solution of the geometric parameters by the mesh boundary, a chain rule based on a differential equation makes the above one-step optimization become possible. FIG. 4 illustrates is a schematic diagram of an exemplary optimization process 400, according to some embodiments of the present disclosure. As shown in FIG. 4, optimization process 400 includes steps S402 and S404.

At step S402, layouts are parameterized, and some layouts and geometric parameters of devices are defined in the layouts (such as describing the length and width of a rectangular shape; describing the radius and center position of a circular shape, etc.). For example, each line can correspond to parameters such as the length and the width. The parameters are variable.

At step S404, the Hamiltonian parameters of the target quantum model are obtained, and then simulating calculation is performed on the layouts to obtain the gradient of the target model parameters to the geometric parameters.

In some embodiments, in the step S404, the parameterized layouts may be analyzed by a solver. In some embodiments, the layout shape is divided to obtain multiple meshes (for example, triangles), and then the gradient of each mesh boundary to the geometric parameters (the gradient of the same mesh to the geometric parameters) is solved.

In some embodiments, the change of the mesh boundary leads to the change of the matrix element of a matrix of the solution system. For example, changes with a certain density are provided on one triangle, and a change of one triangle leads to the change of the matrix element. The matrix element describes the electromagnetic interaction between the ith triangle and the jth triangle. Then, the unknown to be solved (the number of meshes) changes, and the change of the unknown to the Hamiltonian is reflected as the gradient, that is, dρ/dmesh, (where dρ is a differential of the Hamiltonian parameters, and dmesh is a differential of the mesh parameters).

By solving the above matrix, the gradient of the mesh boundary to the geometric parameters is obtained as dmesh/dg (dmesh is a differential of the mesh parameters and dg is a differential of the geometric parameters).

Then the gradient of the target model parameters to the geometric parameters is obtained as dρ/dg. That is, based on the chain rule, the gradient of the target model parameters to the geometric parameters is obtained by dρ/dg=dρ/dmesh×dmesh/dg.

Based on the gradient information, the geometric parameters are adjusted, and the layout design conforming to the target model parameters is obtained by iteration.

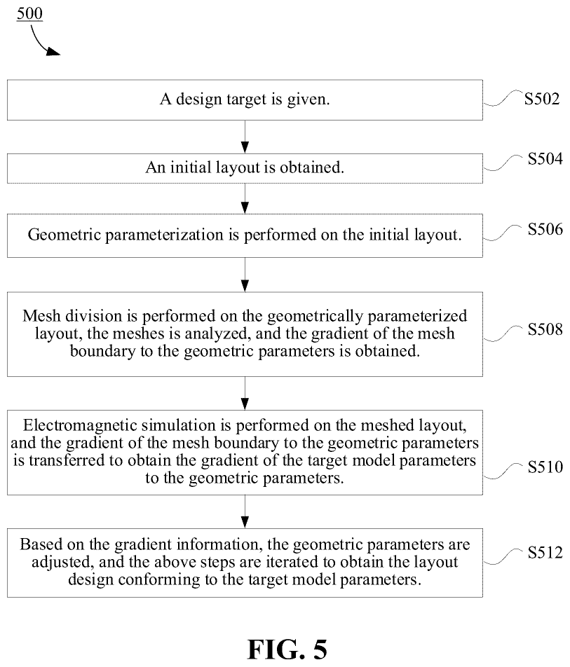

Based on the above process, FIG. 5 is a schematic diagram of an exemplary optimization process 500, according to some embodiments of the present disclosure. As shown in FIG. 5, optimization process 500 includes steps S502 to S512.

At step S502, a design target is given, for example, the target model parameters (i.e., the target Hamiltonian parameters).

At step S504, an initial layout is obtained.

At step S506, geometric parameterization is performed on the initial layout.

At step S508, mesh division is performed on the geometrically parameterized layout, the meshes is analyzed, and the gradient of the mesh boundary to the geometric parameters is obtained.

At step S510, electromagnetic simulation is performed on the meshed layout, and the gradient of the mesh boundary to the geometric parameters is transferred to obtain the gradient of the target model parameters to the geometric parameters.

At step S512, based on the gradient information, the geometric parameters are adjusted, and the above steps are iterated to obtain the layout design conforming to the target model parameters.

The above process may also be realized based on the following ways: obtaining the design target, that is, the target model parameters, i.e., the first Hamiltonian parameters; obtaining the initial layout, and performing geometric parameterization on the initial layout; through simulation, obtaining the gradient of the target model parameters to the geometric parameters of the initial layout and the current Hamiltonian parameters of the initial layout, that is, the second Hamiltonian parameters; and based on the gradient, adjusting the initial layout, so that the second Hamiltonian parameters are optimized to the first Hamiltonian parameters.

Before the electromagnetic simulation is performed, the mesh division is performed on the geometric parameterized layout, the meshes are analyzed, and the first gradient of the mesh boundary to the geometric parameters is obtained. Afterwards, based on the electromagnetic simulation, the second gradient of the Hamiltonian parameters to the mesh boundary is obtained. Based on the first gradient and the second gradient, the gradient of the target model parameters to the geometric parameters of the initial layout is obtained. The electromagnetic simulation includes: performing the electromagnetic simulation on the meshed layout; and transferring the gradient of the mesh boundary to obtain the target model parameters and the gradient of the target model parameters to the geometric parameters.

Through the above processing, a sensitivity relationship between the geometric parameters of the layout and the Hamiltonian parameters, that is, a gradient relationship, may be obtained. In the process of the electromagnetic simulation, it is required to solve the matrix equation, the gradient of the unknown of the matrix equation and a gradient matrix, and gradient optimization treatment is realized by a mesh boundary transfer. Moreover, in an end-to-end optimization design, from geometric shape parameters of the layout of a bottom layer to final quantum model parameters, a matrix solution is all calculated at one time, and the optimization is good, that is, the gradient of the Hamiltonian parameters corresponding to n geometric parameters may be obtained by solving a linear equation. It should be noted that when the gradient is solved, according to some results of calculating the Hamiltonian parameters, a solution process may be accelerated, resource consumption may be reduced, and the efficiency of layout optimization may be greatly improved.

The processing details of the above implementations are described below.

### (I) Layout Design Automation and Optimization

### (1) Parameterized Layout

In order to realize automatic design and parameter optimization, firstly, a suitable model is needed to parameterize the layout. In order to avoid too much abstraction of the model at the beginning, firstly, a predefined shape pattern is used for simulating a manual design process.

(2) Layout with Predefined Patterns

The layout is parameterized by several geometric parameters. A scheme is to create a quantum bit layout by imitating a human design process, including: creating some shapes and size parameters, allocating a relative position (distance vector) between two shapes, and performing Boolean operations (difference and union) on the two shapes according to actual needs. This may not be a relatively good way to define a layout. If some patterns are changed, the definitions of the parameters are also changed. But a more intuitive method is to associate the parameters with the layout itself.

### (3) Auxiliary Operation

### 1) DEFINING SHAPES

Shapes may be defined/imported in the following ways to gradually complete a commonly used shape pattern library:
1. regular shapes (rectangle, trapezoid, triangle, circle, etc.);
2. cycling from parameterized coordinates linearly; and
3. importing from GDS (Graphic Design System) files.

### 2) DEFINING THE RELATIVE POSITION

### 3) DEFINING BOOLEAN OPERATIONS. BOOLEAN OPERATORS INCLUDE “DIFFERENCE” AND “UNION”

### (4) Configuration Optimization

In the preset layout mode, a cost function is calculated with a mesh generator and a surface integral equation (IE) electrostatic solver as the cores.

### (5) Optimization Process

A complete layout, such as double quantum bits (2Q), including a first quantum bit and a second quantum bit, is usually defined by about 100 parameters. The optimization of all parameters is very slow and may lead to infinite possible solutions.

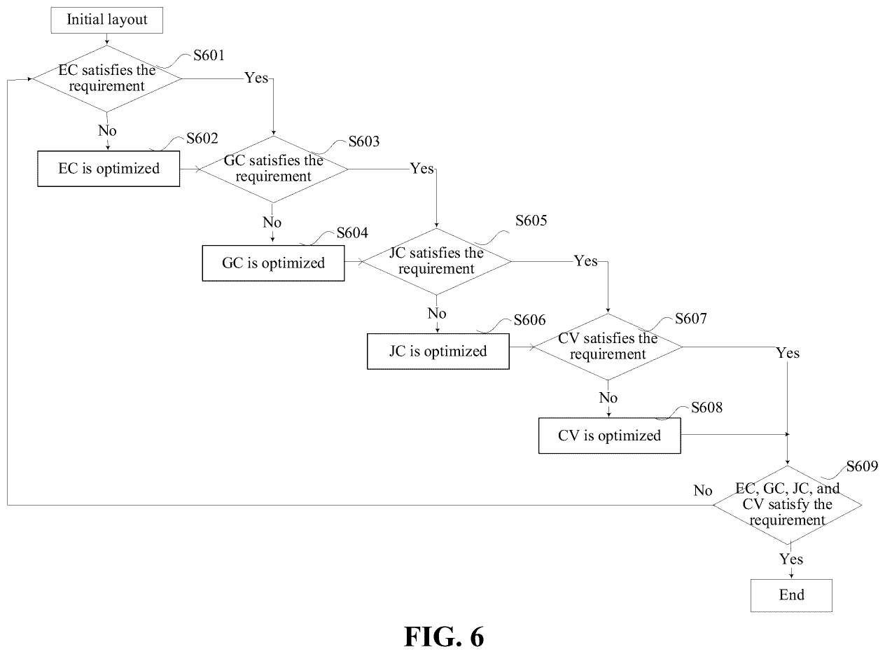

In practical applications, EC, JC (quantum bit-quantum bit capacitance coupling), GC (quantum resonance coupling), and CV (Capacitance due to voltage) are only closely related to a few design parameters, and the coupling between them is relatively weak. FIG. 6 is a schematic diagram of an optimization process 600 provided according to an optional implementation of the present disclosure, as shown in FIG. 6, process 600 includes steps S601 to S609.

At step S601, for an initial layout, EC is evaluated to determine whether it satisfies the design requirements. If EC does not satisfy the design requirement, step S602 is performed. If EC satisfies the design requirements, step S603 is performed.

At step S602, the size of a qa/qb pad, e.g., the size of a first quantum bit pad or a size of a second quantum bit pad, is optimized to obtain a required EC. After EC is optimized, step S603 is performed.

At step S603, GC is evaluated to determine whether it satisfies the design requirements. If GC does not satisfy the design requirements, step S604 is performed. If GC satisfies with the design requirements, step S605 is performed.

At step S604, GC is optimized. After GC is optimized, step 605 is performed.

At step S605, JC is evaluated to determine whether it satisfies the design requirements. If JC does not satisfy the design requirements, step S606 is performed. If JC satisfies the design requirements, step S607 is performed.

At step S606, JC is optimized. After JC is optimized, step 607 is performed.

At step S607, CV is evaluated to determine whether it satisfies the design requirements. If CV does not satisfy the design requirements, step S608 is performed. If CV satisfies the design requirements, step S609 is performed.

At step S608, CV is optimized. After CV is optimized, step S609 is performed.

At step S609, the parameters EC, GC, JC, and CV are evaluated to determine whether they satisfy the design requirements. If all the parameters EC, GC, JC, and CV satisfy the design requirements, optimization process 600 is end. If all the parameters EC, GC, JC, and CV do not satisfy the design requirements, that is, at least one parameter of EC, GC, JC, and CV does not satisfy the design requirements, the process returns to step S601, until all the parameters satisfy the design requirements. When optimizing one parameter, the results of another of one or more parameters which is optimized in previous step(s) may be slightly affected. For example, when GC is optimized at step S604, EC which is optimized in previous step S602 may be affected, so step S601 needs to be performed again to determine whether EC satisfy the design requirement.

In each step of optimization process 600, only one target parameter (EC, GC, JC or CV) is optimized. Therefore, a total number of calls to an EM (electromagnetic) solver may be reduced, and running time is reduced.

### (6) Cost Function

The cost function may be simply defined as a sum of squares of errors to achieve an expected design target. For example, for the EC optimization of N quantum bits, the cost function is expressed as follows:

$$\sqrt{{\sum }_{i}^{N} {( {E}_{c} - {E}_{c}^{t a r} )}^{2}}$$

### (7) Efficiency

The simulation time of a double quantum bit design is shown in the following table.

| Optimization | Time (thicknet | Time (detail network |
|---|---|---|
| process | 36k) | 130k) |
| Optimization EC | 8 min | 200 min |
| Optimization GC | 6 min | 9 min |
| Optimization JC | 4 min | 100 min |
| Optimization CV | 15 min | 350 min |
| Total | ~40 min | ~14 hour |

wherein, under the detail network, it is closed to the upper limit of memory.

### (II) Layout Optimization and Gradient Calculation

### (1) Parameterized Layout

In related technologies, the layout is parameterized by a user-defined geometry creation function, and the parameters are manually defined by a user.

A more general method of parameterized layout is described below.

### 1) GRADIENT CALCULATION

Assuming that the layout is represented by G(\vec{x}) on a surface where \vec{x} is the vector of a parameter to be optimized. Problems to be solved are as follows:

∫_{G(\vec{x})}g(\vec{r},\vec{r}′)ρ(\vec{r}′)d\vec{r}′=V(\vec{r})

where g(\vec{r},\vec{r}′) is Green's function, which is integrated on the surface of the layout. It is worth noting that V(\vec{r}) is independent of \vec{x} because it is related to the voltage distribution (1V or 0V) on the layout metal, and it has nothing to do with the boundary and shape. An unknown number to be solved is ρ(\vec{r}′), and the capacitor matrix and participation ratio may be derived from the distribution of ρ(\vec{r}′).

Therefore, the final gradient of ρ with respect to \vec{x}: ∇_{\vec{x}}ρ(\vec{x}) is desired to be found to accelerate the optimization.

### 2) DERIVATION

The above equation may be simplified as:

A(\vec{x})·ρ(\vec{x})=V

where A is defined as: A(\vec{x})=∫_{G(\vec{x})}d\vec{r}′g(\vec{r},\vec{r}′).

Note that for simplicity, the above formula omits the dependence of \vec{r} in the operator and introduces the dependence of \vec{x}.

Taking the gradient of the equation relative to the layout parameters:

(∇_{\vec{x}}A(\vec{x}))·ρ(\vec{x})+A(\vec{x})·∇_{\vec{x}}ρ(\vec{x})=0

The right side of the above formula is zero, because V is not a function of \vec{x}. ∇_{\vec{x}}ρ(\vec{x}) becomes the solution of the new equation:

A(\vec{x})·∇_{\vec{x}}ρ(\vec{x})=−(∇_{\vec{x}}A(\vec{x}))·ρ(\vec{x})

This problem is simplified as repeatedly using A as a linear equation set and solving the equation set with a new right side. The right side shows that a potential distribution gradient caused by a layout change is generated by a fixed charge distribution.

### 3) DISCRETE FORM

The above formula needs to be decomposed into a matrix form for numerical solution. A standard matrix equation is:

$${\sum }_{j} {\int }_{G ( \vec{x} )} d \vec{r} {Λ}_{i} ( \vec{r} ) {\int }_{G ( \vec{x} )} d {\vec{r}}^{′} g ( \vec{r} , {\vec{r}}^{′} ) {Λ}_{j} ( {\vec{r}}^{′} ) {ρ}_{j} ( \vec{x} ) = {\int }_{G ( \vec{x} )} d \vec{r} {Λ}_{i} ( \vec{r} ) V ( \vec{r} )$$

In the above formula, the unknown is expanded as ρ(\vec{x})=Σⱼρⱼ(\vec{x})Λⱼ(\vec{r}′).

By replacing \vec{x} in the above formula with \vec{x}+Δx, the following formula may be obtained:

$${\sum }_{j} {\int }_{G ( \vec{x} + Δ x )} d \vec{r} {Λ}_{i} ( \vec{r} ) {\int }_{G ( \vec{x} + Δ x )} d {\vec{r}}^{′} g ( \vec{r} , {\vec{r}}^{′} ) {Λ}_{j} ( {\vec{r}}^{′} ) {ρ}_{j} ( \vec{x} + Δx ) = {\int }_{G ( \vec{x} + Δ x )} d \vec{r} {Λ}_{i} ( \vec{r} ) V ( \vec{r} )$$

In order to keep only the term Δx, the above two equations are differentiated.

$${\sum }_{j} {\int }_{Δ G ( \vec{x} )} d \vec{r} {Λ}_{i} ( \vec{r} ) {\int }_{G ( \vec{x} )} d {\vec{r}}^{′} g ( \vec{r} , {\vec{r}}^{′} ) {Λ}_{j} ( {\vec{r}}^{′} ) {ρ}_{j} ( \vec{x} ) + {\sum }_{j} {\int }_{G ( \vec{x} )} d \vec{r} {Λ}_{i} ( \vec{r} ) {\int }_{Δ G ( \vec{x} )} d {\vec{r}}^{′} g ( \vec{r} , {\vec{r}}^{′} ) {Λ}_{j} ( {\vec{r}}^{′} ) {ρ}_{j} ( \vec{x} ) + Δ x {\sum }_{j} {\int }_{G ( \vec{x} )} d \vec{r} {Λ}_{i} ( \vec{r} ) {\int }_{G ( \vec{x} )} d {\vec{r}}^{′} g ( \vec{r} , {\vec{r}}^{′} ) {Λ}_{j} ( {\vec{r}}^{′} ) {∇}_{\vec{x}} {ρ}_{j} ( \vec{x} ) = {\int }_{Δ G ( \vec{x} )} d \vec{r} {Λ}_{i} ( \vec{r} ) V ( \vec{r} )$$

The following relationship is brought into the above formula:

ρⱼ(\vec{x}+Δx)=ρⱼ(\vec{x})+Δx·∇_{\vec{x}}ρⱼ(\vec{x})

which is expressed as:

ΔG(\vec{x})=G(\vec{x}+Δx)−G(\vec{x})

As both sides of the equation are equal, therefore:

$${\sum }_{j} {\int }_{G ( \vec{x} )} d \vec{r} {Λ}_{i} ( \vec{r} ) {\int }_{G ( \vec{x} )} d {\vec{r}}^{′} g ( \vec{r} , {\vec{r}}^{′} ) {Λ}_{j} ( {\vec{r}}^{′} ) {∇}_{\vec{x}} {ρ}_{j} ( \vec{x} ) = - {\sum }_{j} {\int }_{G ( \vec{x} )} d \vec{r} {Λ}_{i} ( \vec{r} ) \frac{1}{Δ x} {\int }_{Δ G ( \vec{x} )} d {\vec{r}}^{′} g ( \vec{r} , {\vec{r}}^{′} ) {Λ}_{j} ( {\vec{r}}^{′} ) {ρ}_{j} ( \vec{x} )$$

The last term on the right side of the above formula is simplified as a line integral:

$$\frac{1}{Δ x} {\int }_{Δ G ( \vec{x} )} d {\vec{r}}^{′} g ( \vec{r} , {\vec{r}}^{′} ) {Λ}_{j} ( {\vec{r}}^{′} ) {ρ}_{j} ( \vec{x} ) = \int dlg ( \vec{r} , {\vec{r}}^{′} ) {Λ}_{j} ( {\vec{r}}^{′} ) {ρ}_{j} ( \vec{x} )$$

The above description form is the same as the operator form in derivation.

### 4) GRADIENT OF OPERATOR

In order to obtain the layout gradient correctly, it is necessary to evaluate the gradient of the operator:

∇_{\vec{x}}A(\vec{x})

or express it in a discrete form:

$$\frac{1}{Δ x} {\int }_{Δ G ( \vec{x} )} d {\vec{r}}^{′} g ( \vec{r} , {\vec{r}}^{′} ) {Λ}_{j} ( {\vec{r}}^{′} ) {ρ}_{j} ( \vec{x} )$$

### 5) EXAMPLES

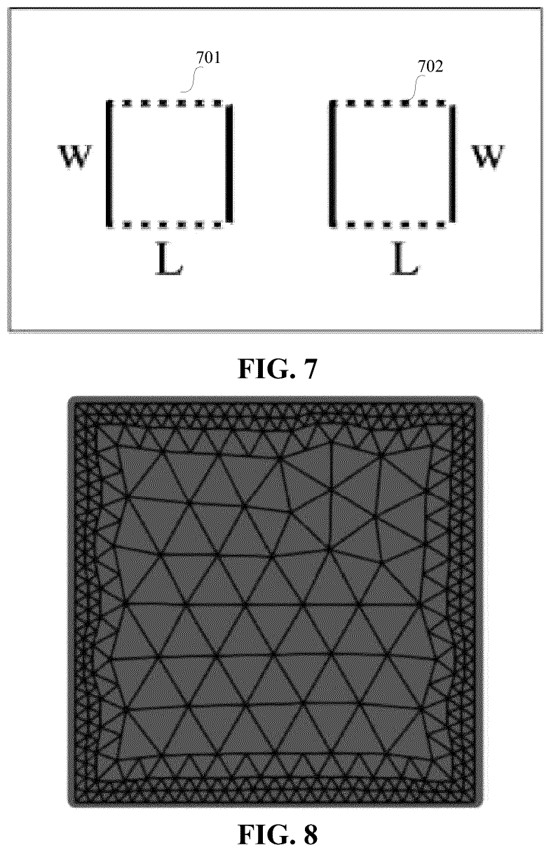

FIG. 7 is a schematic diagram of a quantum bit pad provided according to an optional implementation of the present disclosure. As shown in FIG. 7, consider a simple example as follows: two identical rectangular quantum bit pads 701, 702 are parameterized by two parameters W and L, and a center of each pad (701, 702) is fixed. The surrounding ground plane is fixed.

The derivative of the charge distribution to the parameter L is:

$$\frac{dp}{dw} = {A}^{- 1} \cdot B \cdot ρ$$

where the matrix element of B is:

[B]ᵢⱼ=−∫_{G(\vec{x})}d\vec{r}Λᵢ(\vec{r})∫_{P}dlg(\vec{r},\vec{r}′)Λⱼ(\vec{r}′)

where the integration path P is a line corresponding to a side L in FIG. 7; and the integral surface G is the whole layout.

If a straight line corresponding to a single parameter change may be found, the derivative thereof may be found.

### 6) NUMERICAL REALIZATION

The main steps of numerical realization are as follows:

Firstly, it is necessary to find out the changes of geometric shapes and meshes caused by parameter changes.
1. A change of the geometric shapes is characterized by a change of polygon vertex coordinates.
2. As polygons are uniquely defined by boundary nodes, only the coordinates of the boundary nodes have non-zero derivatives with respect to parameter changes. Then due to the change of parameters xᵢ, a change of the coordinates \vec{r} of the boundary nodes may be written as:

$$\frac{δ \vec{r}}{{δx}_{i}}$$

3. A change of these boundary nodes may be transformed into a change of boundary edges, and the change of the boundary edges leads to the increase or decrease of the area of a triangle to which the boundary edges are attached.
4. The integral path P and the coefficient of B in the formula are well defined.

### (III) Evaluation of Matrix Element

A governing equation generated by the gradient of electrostatic parameters relative to the geometric parameters is as follows:

A(\vec{x})·∇_{\vec{x}}ρ=−(∇_{\vec{x}}A(\vec{x})·ρ(\vec{x})

where A is an operation symbol/matrix related to the charge density ρ and the excitation voltage V: A·ρ=V.

### (1) Calculating the Matrix Element of ∇_{\vec{x}}A

The matrix A is expressed as:

$${[ A ]}_{ij} = \frac{1}{4 π} {\int }_{{T}_{i}} d \vec{r} \frac{1}{{A}_{i}} {\int }_{{T}_{i}} d {\vec{r}}^{′} \frac{1}{\vert \vec{r} - {\vec{r}}^{′} \vert} \frac{1}{{A}_{j}} = \frac{1}{4 {πA}_{i} {A}_{j}} {\int }_{{T}_{i}} d \vec{r} {\int }_{{T}_{j}} d {\vec{r}}^{′} \frac{1}{\vert \vec{r} - {\vec{r}}^{′} \vert}$$

where Aᵢ and Aⱼ are the areas of triangles Tᵢ and Tⱼ.

Assuming that x is a geometric parameter, and the variation quantity thereof causes a coordinate shift in the triangle. This may be converted into changes Tᵢ and Tⱼ in the integral domain. Therefore, the following formula may be obtained:

$${[ {δ}_{x} A ]}_{ij} = \frac{1}{4 {πA}_{i} {A}_{j}} {δ}_{x} {\int }_{{T}_{i}} d \vec{r} {\int }_{{T}_{j}} d {\vec{r}}^{′} \frac{1}{\vert \vec{r} - {\vec{r}}^{′} \vert}$$

If further consideration is given to a change of the areas Aᵢ and Aⱼ, the gradient acts on the area:

$$- {( \frac{{δ}_{x} {A}_{i}}{{A}_{i}} + \frac{{δ}_{x} {A}_{j}}{{A}_{j}} ) [ A ]}_{ij}$$

### (2) Gradient on the Integral

The integral form may be expressed as:

$${I}_{0} ( x , {T}_{i} , {T}_{j} ) = {\int }_{{T}_{i} ( x )} d \vec{r} {\int }_{{T}_{j} ( x )} d {\vec{r}}^{′} \frac{1}{\vert \vec{r} - {\vec{r}}^{′} \vert}$$

where \vec{r} is located on Tᵢ(x), and \vec{r}′ is located on Tⱼ(x).

The following integral is considered, which is related to the expression [δₓA]ᵢⱼ:

$${I}_{1} ( x , {T}_{i} , {T}_{j} ) = {δ}_{x} {I}_{0} ( x , {T}_{i} , {T}_{j} ) = {δ}_{x} {\int }_{{T}_{i} ( x )} d \vec{r} {\int }_{{T}_{j} ( x )} d {\vec{r}}^{′} \frac{1}{\vert \vec{r} - {\vec{r}}^{′} \vert}$$

Through some derivations and simplification, the following may be obtained:

$${I}_{1} ( x , {T}_{i} , {T}_{j} ) = {∮}_{δ {T}_{i} ( x )} d \vec{r} ( \vec{v} \cdot \hat{n} ) {\int }_{{T}_{j} ( x )} d {\vec{r}}^{′} \frac{1}{\vert \vec{r} - {\vec{r}}^{′} \vert} + {\int }_{{T}_{i} ( x )} d \vec{r} {∮}_{δ {T}_{i} ( x )} d {\vec{r}}^{′} ( {\vec{v}}^{′} \cdot {\hat{n}}^{′} ) \frac{1}{\vert \vec{r} - {\vec{r}}^{′} \vert}$$

where \vec{r} and \vec{r}′ are not functions of x,

$${δ}_{x} \frac{1}{\vert \vec{r} - {\vec{r}}^{′} \vert} = 0.$$

A variant of x causes the triangle boundary to change: δTᵢ and δTⱼ; \vec{v} represents a speed of a change of a boundary δTᵢ, and \vec{v}′ represents a speed of a change of a boundary δTⱼ. The normal directions of the boundary are \hat{n} and \hat{n}′. Therefore, the projection of the velocity in the normal direction contributes to the integral of the dot product, i.e., \vec{v}·\hat{n} and \vec{v}′·\hat{n}′.

Finally, a hyperboloid integral is reduced to a sum of two surface integrals plus surface integrals.

### (3) Extreme Cases: Small Triangle and Long Distance

If triangles Tᵢ and Tⱼ are small enough compared with the distance |\vec{r}−\vec{r}′|, the integrand

$$\frac{1}{\vert \vec{r} - {\vec{r}}^{′} \vert}$$

may be considered constant. Therefore, I₁≈cI₀, where c is the variation quantity of the triangle size.

### (IV) Mesh Processing and Gradient Information

### (1) Mesh Generation and Processing

### 1) THE MAIN STEPS ARE AS FOLLOWS

1. There is a method for generating a layout (plane geometry) by G, with only a few parameters \vec{x}, where each element in the vector \vec{x} is a geometric parameter:

\vec{x}→G(x)
2. The rate of change from \vec{x} to \vec{x}+d\vec{x} produces different layouts G(\vec{x}+d\vec{x})=G(\vec{x})+δG. It can be assumed that a change of \vec{x} does not affect the topology of the layout. Therefore, δG is a change of the boundary:

\vec{x}+d\vec{x}→G(x)+δₓG
An important problem is to neatly represent δₓG.
3. The change of the boundary δₓG is recorded as several vertices pᵢ Each vertex is associated with a vector representing a coordinate change thereof.

δₓG→{(pᵢ,vᵢ)}
where pᵢ is the vertex of the vertex geometry, and vᵢ is the coordinate that changes with a change of \vec{x}.
4. The vertices are marked with non-zero vectors, and are cycled on lines on the boundary. If any endpoint is marked, a line represented as lⱼ should also be labeled because all points on the line are different.

δₓG→{(pᵢ,vᵢ)}+{lⱼ}
It should be noted that it is possible that change vectors of the two endpoints are parallel to the straight line. In this case, the line does not change and does not need to be marked.
5. Mesh generation Along each marked line lⱼ, all mesh points pⱼ on the line are found, and an interpolation change vector vⱼ is obtained based on vectors at both ends.

{lⱼ}→{(pⱼ,vⱼ)}

Generally speaking, a change of the mesh relative to a parameter δₓG is simply expressed as a set of boundary points plus vectors.

δₓG→{(pₖ,vₖ)}

This representation is compatible with a mesh refinement scheme.

### 2) EXAMPLES

FIG. 8 is a schematic diagram of mesh generation according to an optional implementation of the present disclosure.

### (2) Implementation Details

Mesh generation: in the optional implementation of the present disclosure, a mesh is generated for each shape, and the step of mesh generation is only based on geometry to generate mesh marker points/lines.

It should be noted that for each of the foregoing method embodiments, for ease of description, the method embodiment is described as a series of action combinations, but a person skilled in the art should understand that the present disclosure is not limited to an order of described actions, because according to the present disclosure, some steps may be performed in another order or at the same time. Secondly, a person skilled in the art should also understand that the embodiments described in the specification all belong to preferred embodiments, and the involved actions and modules are not necessarily required by the present disclosure.

According to the descriptions in the foregoing implementations, a person skilled in the art may clearly learn that the quantum layout optimization method according to the above embodiments may be implemented by relying on software and a required commodity hardware platform or by using hardware, but in many cases, the former is a preferred implementation. Based on such an understanding, the technical solutions of the present disclosure essentially, or the part contributing to the prior art, may be represented in a form of a software product. The computer software product is stored in a computer-readable storage medium (for example, a ROM/RAM, a magnetic disk, or an optical disc) and includes several instructions to enable a terminal device (which may be a mobile phone, a computer, a server, a network device, and the like) to perform the methods described in the embodiments of the present disclosure.

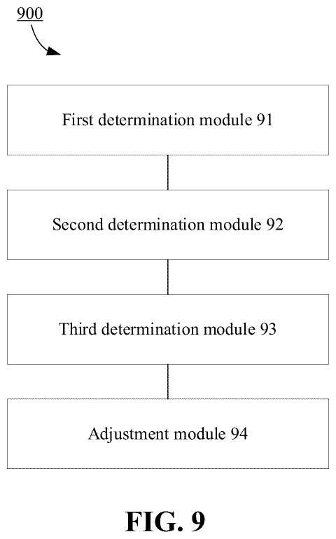

Embodiments of the present disclosure further provide a device for implementing the above quantum layout optimization method. FIG. 9 is a structural block diagram of an example quantum layout optimization device 900, according to some embodiments of the present disclosure. As shown in FIG. 9, device 900 includes: a first determination module 91, a second determination module 92, a third determination module 93, and an adjustment module 94.

First determination module 91 is configured to determine target Hamiltonian parameters of a quantum device. Second determination module 92 is connected to first determination module 91, and is configured to determine an initial quantum layout of the quantum device and initial geometric parameters of the initial quantum layout. Third determination module 93 is connected to second determination module 92, and is configured to determine a target gradient of Hamiltonian parameters of the quantum device to geometric parameters of the initial quantum layout. Adjustment module 94 is connected to third determination module 93, and is configured to adjust the initial geometric parameters based on the target gradient, so that the Hamiltonian parameters of the quantum device are the target Hamiltonian parameters, and a target quantum layout is obtained.

Herein, it should be noted that: first determination module 91, second determination module 92, third determination module 93 and adjustment module 94 correspond to steps S202 to S208 in method 200, and the four modules and the corresponding steps implement the same examples and application scenarios, but are not limited to the content disclosed in the above embodiments. It should be noted that as a part of the device, the above modules may run in the computer terminal 100 shown in FIG. 1.

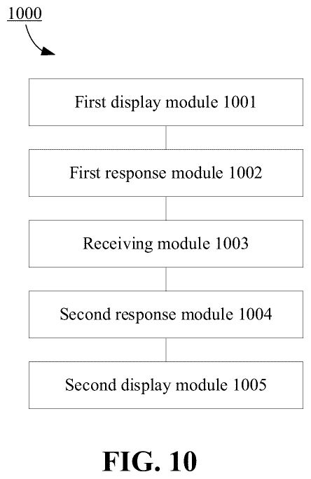

According to the embodiments of the present disclosure, a device for implementing the above quantum layout optimization method is further provided. FIG. 10 is a structural block diagram of a quantum layout optimization device 1000 according to some embodiments of the present disclosure. As shown in FIG. 10, device 1000 includes: a first display module 1001, a first response module 1002, a receiving module 1003, a second response module 1004, and a second display module 1005.

First display module 1001 is configured to display an input control on an interactive interface. First response module 1002 is connected to first display module 1001, and is configured to display target Hamiltonian parameters of a quantum device, an initial quantum layout of the quantum device and initial geometric parameters of the initial quantum layout on the interactive interface in response to the operation of the input control. Receiving module 1003 is connected to first response module 1002, and is configured to receive a quantum layout optimization instruction. Second response module 1004 is connected to receiving module 1003, and is configured to determine a target gradient of Hamiltonian parameters of the quantum device to geometric parameters of the initial quantum layout in response to the quantum layout optimization instruction, and adjust the initial geometric parameters based on the target gradient, so that the Hamiltonian parameters of the quantum device are the target Hamiltonian parameters, and a target quantum layout is obtained. Second display module 1005 is connected to second response module 1004, and is configured to display the target quantum layout on the interactive interface.

Herein, it should be noted that first display module 1001, first response module 1002, receiving module 1003, second response module 1004, and second display module 1005 correspond to steps S302 to S310 in method 300, and the five modules and the corresponding steps implement the same examples and application scenarios, but are not limited to the content disclosed in the above embodiments. It should be noted that as a part of the device, the above modules may run in the computer terminal 100 shown in FIG. 1.

The embodiments of the present disclosure may further provide a computer terminal, which can be any computer terminal device in a computer terminal group. In some embodiments, the above computer terminal may also be replaced by terminal equipment such as a mobile terminal.

In some embodiments, the computer terminal may be located in at least one of a plurality of network devices in a computer network.

In some embodiments, the computer terminal may execute a program code of the following steps in a quantum layout optimization method of an application program: determining target Hamiltonian parameters of a quantum device; determining an initial quantum layout of the quantum device and initial geometric parameters of the initial quantum layout; determining a target gradient of Hamiltonian parameters of the quantum device to geometric parameters of the initial quantum layout; and adjusting the initial geometric parameters based on the target gradient, so that the Hamiltonian parameters of the quantum device are the target Hamiltonian parameters, and a target quantum layout is obtained.

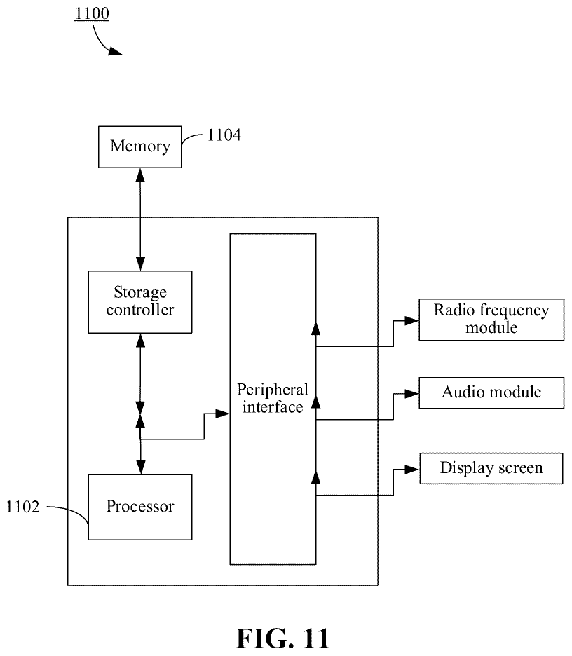

In some embodiments, FIG. 11 is a structural block diagram of a computer terminal 1100 according to some embodiments of the present disclosure. As shown in FIG. 11, computer terminal 1100 may include: one or more (only one is shown in the figure) processors 1102, a memory 1104, and the like.

Memory 1104 may be configured to store software programs and modules, such as program instructions/modules corresponding to the quantum layout optimization method and the device in the embodiments of the present disclosure. Processor 1102 executes various functional applications and data processing by running the software programs and the modules stored in the memory, that is, the above quantum layout optimization method is realized. Memory 1104 may include a high-speed random memory, and may also include a non-volatile memory, for example, one or more magnetic storage devices, a flash memory, or another non-volatile solid-state memory. In some examples, memory 1104 may further include memories remotely disposed relative to processor 1102, and the remote memories may be connected to a computer terminal through a network. Examples of the above network include, but are not limited to, the Internet, an intranet, a local area network, a mobile communication network, and a combination thereof.

Processor 1102 may call information and application programs stored in memory 1104 through a transmission device to perform the following steps: determining target Hamiltonian parameters of a quantum device; determining an initial quantum layout of the quantum device and initial geometric parameters of the initial quantum layout; determining a target gradient of Hamiltonian parameters of the quantum device to geometric parameters of the initial quantum layout; and adjusting the initial geometric parameters based on the target gradient, so that the Hamiltonian parameters of the quantum device are the target Hamiltonian parameters, and a target quantum layout is obtained.

In some embodiments, processor 1102 may also perform the program code of the following steps: performing mesh division on the initial quantum layout of the quantum device to obtain a mesh boundary of the initial quantum layout; determining a first gradient of the mesh boundary to the geometric parameters of the initial quantum layout; determining a second gradient of the Hamiltonian parameters of the quantum device to the mesh boundary; and determining the target gradient of the Hamiltonian parameters of the quantum device to the geometric parameters of the initial quantum layout based on the first gradient and the second gradient.

In some embodiments, processor 1102 may also perform the program code of the following steps: dividing the initial quantum layout based on a predetermined basic pattern to obtain a plurality of meshes of the predetermined basic pattern; and connecting vertices on the boundary of the initial quantum layout in the plurality of meshes into lines to obtain the mesh boundary of the initial quantum layout.

In some embodiments, processor 1102 may also perform the program code of the following steps: determining a mesh boundary including a target number of meshes on the boundary obtained by dividing the initial quantum layout based on a predetermined basic pattern; and determining the first gradient of the mesh boundary to the geometric parameters of the initial quantum layout based on a change of the target number relative to the geometric parameters of the initial quantum layout.

In some embodiments, processor 1102 may also perform the program code of the following steps: performing electromagnetic simulation on the initial quantum layout of the quantum device, where a change of the Hamiltonian parameters of the quantum device is relative to a change of the mesh boundary; and determining the second gradient of the Hamiltonian parameters of the quantum device to the mesh boundary based on the change of the Hamiltonian parameters of the quantum device relative to the change of the mesh boundary.

In some embodiments, processor 1102 may also perform the program code of the following steps: determining the Hamiltonian parameters of the quantum device with the geometric parameters of the initial quantum layout as variables by taking the mesh boundary as an intermediate transfer quantity in the first gradient and the second gradient; and determining the target gradient of the Hamiltonian parameters to the geometric parameters of the initial quantum layout.

In some embodiments, processor 1102 may also perform the program code of the following steps: determining an adjustment direction of the initial geometric parameters based on the target gradient; and adjusting the initial geometric parameters based on the adjustment direction multiple times, so that the Hamiltonian parameters of the quantum device are the target Hamiltonian parameters, and the target quantum layout is obtained.

In some embodiments, processor 1102 may also perform the program code of the following steps: the quantum device includes a Fluxonium quantum bit.

Processor 1102 may call information and application programs stored in memory 1104 through a transmission device to perform the following steps: displaying an input control on an interactive interface; displaying target Hamiltonian parameters of a quantum device, an initial quantum layout of the quantum device and initial geometric parameters of the initial quantum layout on the interactive interface in response to the operation of the input control; receiving a quantum layout optimization instruction; determining a target gradient of Hamiltonian parameters of the quantum device to geometric parameters of the initial quantum layout in response to the quantum layout optimization instruction, and adjusting the initial geometric parameters based on the target gradient, so that the Hamiltonian parameters of the quantum device are the target Hamiltonian parameters, and a target quantum layout is obtained; and displaying the target quantum layout on the interactive interface.

A quantum layout optimization scheme is provided according to the embodiments of the present disclosure. Firstly, the target Hamiltonian parameters of the quantum device, the initial quantum layout of the quantum device and the initial geometric parameters of the initial quantum layout are determined by a gradient calculation method. The initial quantum layout is simulated and calculated based on the target Hamiltonian and the initial geometric parameters to obtain the target gradient of the target Hamiltonian relative to the initial geometric parameters, that is, the change required to adjust the initial geometric parameters to the target geometric parameters is obtained, and the purpose of the geometric parameters of the initial quantum layout being directly adjusted to the geometric parameters of the target quantum layout based on the target gradient is achieved. After the quantum layout is adjusted to the target geometric parameters, the quantum device corresponding to the quantum layout can also reach the target Hamiltonian parameters, thus realizing the target gradient of the Hamiltonian parameters based on the quantum device to the geometric parameters of the initial quantum layout. The initial geometric parameters are adjusted directly to improve the technical effect of quantum layout optimization efficiency, and then the technical problems of complicated operation and low efficiency during adjusting the parameters of the quantum layout are solved.

A person of ordinary skill in the art can understand that the structure shown in FIG. 11 is only illustrative, and computer terminal 1100 may also be a smart phone (such as an Android mobile phone and an iOS mobile phone), a tablet computer, a palmtop computer, a mobile Internet device (MID), a PAD and other terminal devices. FIG. 11 does not limit the structure of the above electronic device. For example, the computer terminal 1100 may also include more or fewer components (such as a network interface and a display device) than those shown in FIG. 11, or has a configuration different from that shown in FIG. 11.

A person of ordinary skill in the art may understand that all or some of the steps of various methods in the above embodiments may be completed by a program instructing hardware related to the terminal device. The program may be stored in a computer-readable storage medium. The computer-readable storage medium may include: a flash drive, a read-only memory (ROM), a random-access memory (RAM), a magnetic disk, an optical disc, and the like.

Embodiments of the present disclosure further provide a computer-readable storage medium. In some embodiments, the computer-readable storage medium may be used for storing the program code executed by the quantum layout optimization method.

In some embodiments, the computer-readable storage medium may be located in any computer terminal in a computer terminal group in a computer network or in any mobile terminal in a mobile terminal group.

In some embodiments, the computer-readable storage medium is set to store the program code used for executing the quantum layout optimization method in the above embodiments.

The embodiments may further be described using the following clauses:
1. A quantum layout optimization method, comprising:
determining target Hamiltonian parameters of a quantum device;
determining an initial quantum layout of the quantum device and initial geometric parameters of the initial quantum layout;
determining a target gradient of Hamiltonian parameters of the quantum device to geometric parameters of the initial quantum layout; and
adjusting the initial geometric parameters based on the target gradient to have the Hamiltonian parameters of the quantum device being the target Hamiltonian parameters to obtain a target quantum layout.
2. The method according to clause 1, wherein the determining the target gradient of Hamiltonian parameters of the quantum device to geometric parameters of the initial quantum layout comprises:
performing mesh division on the initial quantum layout of the quantum device to obtain a mesh boundary of the initial quantum layout;
determining a first gradient of the mesh boundary to the geometric parameters of the initial quantum layout;
determining a second gradient of the Hamiltonian parameters of the quantum device to the mesh boundary; and
determining the target gradient of the Hamiltonian parameters of the quantum device to the geometric parameters of the initial quantum layout based on the first gradient and the second gradient.
3. The method according to clause 2, wherein the performing mesh division on the initial quantum layout of the quantum device to obtain a mesh boundary of the initial quantum layout comprises:
dividing the initial quantum layout based on a predetermined basic pattern to obtain a plurality of meshes of the predetermined basic pattern; and
connecting vertices on the boundary of the initial quantum layout in the plurality of meshes into lines to obtain the mesh boundary of the initial quantum layout.
4. The method according to clause 2, wherein the determining the first gradient of the mesh boundary to the geometric parameters of the initial quantum layout comprises:
determining a mesh boundary including a target number of meshes on the boundary obtained by dividing the initial quantum layout based on a predetermined basic pattern; and
determining the first gradient of the mesh boundary to the geometric parameters of the initial quantum layout based on a change of the target number relative to the geometric parameters of the initial quantum layout.
5. The method according to clause 2, wherein the determining the second gradient of the Hamiltonian parameters of the quantum device to the mesh boundary comprises:
performing electromagnetic simulation on the initial quantum layout of the quantum device, wherein a change of the Hamiltonian parameters of the quantum device is relative to a change of the mesh boundary; and
determining the second gradient of the Hamiltonian parameters of the quantum device to the mesh boundary based on the change of the Hamiltonian parameters of the quantum device relative to the change of the mesh boundary.
6. The method according to clause 2, wherein the determining the target gradient of the Hamiltonian parameters of the quantum device to the geometric parameters of the initial quantum layout based on the first gradient and the second gradient comprises:
determining the Hamiltonian parameters of the quantum device with the geometric parameters of the initial quantum layout as variables by taking the mesh boundary as an intermediate transfer quantity in the first gradient and the second gradient; and
determining the target gradient of the Hamiltonian parameters to the geometric parameters of the initial quantum layout.
7. The method according to any one of clauses 1 to 6, wherein the adjusting the initial geometric parameters based on the target gradient to have the Hamiltonian parameters of the quantum device being the target Hamiltonian parameters to obtain the target quantum layout comprises:
determining an adjustment direction of the initial geometric parameters based on the target gradient; and
adjusting the initial geometric parameters based on the adjustment direction multiple times to have the Hamiltonian parameters of the quantum device being the target Hamiltonian parameters to obtain the target quantum layout.
8. The method according to clause 7, wherein the quantum device comprises a Fluxonium quantum bit.
9. A quantum layout optimization method, comprising:
displaying an input control on an interactive interface;
displaying target Hamiltonian parameters of a quantum device, an initial quantum layout of the quantum device and initial geometric parameters of the initial quantum layout on the interactive interface in response to the operation of the input control;
receiving a quantum layout optimization instruction;
determining a target gradient of Hamiltonian parameters of the quantum device to geometric parameters of the initial quantum layout in response to the quantum layout optimization instruction, and adjusting the initial geometric parameters based on the target gradient, so that the Hamiltonian parameters of the quantum device are the target Hamiltonian parameters, and a target quantum layout is obtained; and
displaying the target quantum layout on the interactive interface.
10. A quantum layout optimization device, comprising:
a first determination module, configured to determine target Hamiltonian parameters of a quantum device;
a second determination module, configured to determine an initial quantum layout of the quantum device and initial geometric parameters of the initial quantum layout;
a third determination module, configured to determine a target gradient of Hamiltonian parameters of the quantum device to geometric parameters of the initial quantum layout; and
an adjustment module, configured to adjust the initial geometric parameters based on the target gradient, so that the Hamiltonian parameters of the quantum device are the target Hamiltonian parameters, and a target quantum layout is obtained.
11. A computer-readable storage medium, comprising a stored program, wherein equipment on which the computer-readable storage medium is located is controlled to execute the quantum layout optimization method according to any one of clauses 1 to 9 when executing the program.
12. A computer device, comprising: a memory and a processor,
the memory storing a computer program, and
the processor being configured to execute the computer program stored in the memory, and implementing the quantum layout optimization method according to any one of claims 1 to 9 when the computer program runs.

It should be noted that, the relational terms herein such as “first” and “second” are used only to differentiate an entity or operation from another entity or operation, and do not require or imply any actual relationship or sequence between these entities or operations. Moreover, the words “comprising,” “having,” “containing,” and “including,” and other similar forms are intended to be equivalent in meaning and be open ended in that an item or items following any one of these words is not meant to be an exhaustive listing of such item or items, or meant to be limited to only the listed item or items.

As used herein, unless specifically stated otherwise, the term “or” encompasses all possible combinations, except where infeasible. For example, if it is stated that a database may include A or B, then, unless specifically stated otherwise or infeasible, the database may include A, or B, or A and B. As a second example, if it is stated that a database may include A, B, or C, then, unless specifically stated otherwise or infeasible, the database may include A, or B, or C, or A and B, or A and C, or B and C, or A and B and C.

In the foregoing specification, embodiments have been described with reference to numerous specific details that can vary from implementation to implementation. Certain adaptations and modifications of the described embodiments can be made. Other embodiments can be apparent to those skilled in the art from consideration of the specification and practice of the disclosure disclosed herein. It is intended that the specification and examples be considered as exemplary only, with a true scope and spirit of the disclosure being indicated by the following claims. It is also intended that the sequence of steps shown in figures are only for illustrative purposes and are not intended to be limited to any particular sequence of steps. As such, those skilled in the art can appreciate that these steps can be performed in a different order while implementing the same method.

It should be understood that the disclosed technical content may be implemented in other ways. The apparatus embodiments described above are only schematic. For example, the division of the units is only a logical function division. In actual implementations, there may be another division manner. For example, multiple units or components may be combined or integrated into another system, or some features can be ignored or not implemented. In addition, the displayed or discussed mutual coupling or direct coupling or communication connection may be indirect coupling or communication connection through some interfaces, units, or modules, which may be in electrical or other forms.

The units described as separate components may or may not be physically separated, and the components displayed as units may or may not be physical units, that is, they may be located in one place or may be distributed to a plurality of network units. Part of or all the units may be selected according to actual needs to achieve the purpose of the solution of the present embodiment.

In addition, the functional units in various embodiments of the present disclosure may be integrated into one processing unit, or each unit may exist alone physically, or two or more units may be integrated into one unit. The integrated units described above may be implemented either in the form of hardware or in the form of a software functional unit.

If the integrated units are implemented in the form of a software functional unit and sold or used as an independent product, they may be stored in a quantum computer-readable storage medium. Based on such an understanding, the technical solutions of the present disclosure essentially, or the part making contributions to the prior art, or all or part of the technical solutions may be embodied in the form of a software product. The quantum computer software product is stored in a storage medium and includes several instructions used for causing a quantum computer device to execute all or part of steps of the methods in various embodiments of the present disclosure.

The above are only preferred implementations of the present disclosure. It should be pointed out that, for those of ordinary skill in the art, several improvements and retouches may further be made without departing from the principles of the present disclosure. These improvements and retouches should also be regarded as the scope of protection of the present specification.

In the drawings and specification, there have been disclosed exemplary embodiments. However, many variations and modifications can be made to these embodiments. Accordingly, although specific terms are employed, they are used in a generic and descriptive sense only and not for purposes of limitation.

What is claimed is:

1. A quantum layout optimization method, comprising:
determining target Hamiltonian parameters of a quantum device;
determining an initial quantum layout of the quantum device and initial geometric parameters of the initial quantum layout;
determining a target gradient of Hamiltonian parameters of the quantum device to geometric parameters of the initial quantum layout; and
adjusting the initial geometric parameters based on the target gradient to have the Hamiltonian parameters of the quantum device be the target Hamiltonian parameters to obtain a target quantum layout.

2. The method according to claim 1, wherein the determining the target gradient of Hamiltonian parameters of the quantum device to geometric parameters of the initial quantum layout comprises:
performing mesh division on the initial quantum layout of the quantum device to obtain a mesh boundary of the initial quantum layout;
determining a first gradient of the mesh boundary to the geometric parameters of the initial quantum layout;
determining a second gradient of the Hamiltonian parameters of the quantum device to the mesh boundary; and
determining the target gradient of the Hamiltonian parameters of the quantum device to the geometric parameters of the initial quantum layout based on the first gradient and the second gradient.

3. The method according to claim 2, wherein performing mesh division on the initial quantum layout of the quantum device to obtain a mesh boundary of the initial quantum layout comprises:
dividing the initial quantum layout based on a predetermined basic pattern to obtain a plurality of meshes of the predetermined basic pattern; and
connecting vertices on the boundary of the initial quantum layout in the plurality of meshes into lines to obtain the mesh boundary of the initial quantum layout.

4. The method according to claim 2, wherein the determining the first gradient of the mesh boundary to the geometric parameters of the initial quantum layout comprises:
determining a mesh boundary including a target number of meshes on the boundary obtained by dividing the initial quantum layout based on a predetermined basic pattern; and
determining the first gradient of the mesh boundary to the geometric parameters of the initial quantum layout based on a change of the target number relative to the geometric parameters of the initial quantum layout.

5. The method according to claim 2, wherein the determining the second gradient of the Hamiltonian parameters of the quantum device to the mesh boundary comprises:
performing electromagnetic simulation on the initial quantum layout of the quantum device, wherein a change of the Hamiltonian parameters of the quantum device is relative to a change of the mesh boundary; and
determining the second gradient of the Hamiltonian parameters of the quantum device to the mesh boundary based on the change of the Hamiltonian parameters of the quantum device relative to the change of the mesh boundary.

6. The method according to claim 2, wherein the determining the target gradient of the Hamiltonian parameters of the quantum device to the geometric parameters of the initial quantum layout based on the first gradient and the second gradient comprises:
determining the Hamiltonian parameters of the quantum device with the geometric parameters of the initial quantum layout as variables by taking the mesh boundary as an intermediate transfer quantity in the first gradient and the second gradient; and
determining the target gradient of the Hamiltonian parameters to the geometric parameters of the initial quantum layout.

7. The method according to claim 1, wherein adjusting the initial geometric parameters based on the target gradient to have the Hamiltonian parameters of the quantum device be the target Hamiltonian parameters to obtain the target quantum layout comprises:
determining an adjustment direction of the initial geometric parameters based on the target gradient; and
adjusting the initial geometric parameters based on the adjustment direction multiple times to have the Hamiltonian parameters of the quantum device be the target Hamiltonian parameters to obtain the target quantum layout.

8. The method according to claim 7, wherein the quantum device comprises a Fluxonium quantum bit.

9. An apparatus for quantum layout optimization, the apparatus comprising:
a memory configured to store instructions; and
one or more processors configured to execute the instructions to cause the apparatus to perform:
determining target Hamiltonian parameters of a quantum device;
determining an initial quantum layout of the quantum device and initial geometric parameters of the initial quantum layout;
determining a target gradient of Hamiltonian parameters of the quantum device to geometric parameters of the initial quantum layout; and
adjusting the initial geometric parameters based on the target gradient to have the Hamiltonian parameters of the quantum device be the target Hamiltonian parameters to obtain a target quantum layout.

10. The apparatus according to claim 9, wherein the one or more processors are further configured to execute the instructions to cause the apparatus to perform:
performing mesh division on the initial quantum layout of the quantum device to obtain a mesh boundary of the initial quantum layout;
determining a first gradient of the mesh boundary to the geometric parameters of the initial quantum layout;
determining a second gradient of the Hamiltonian parameters of the quantum device to the mesh boundary; and
determining the target gradient of the Hamiltonian parameters of the quantum device to the geometric parameters of the initial quantum layout based on the first gradient and the second gradient.

11. The apparatus according to claim 10, wherein the one or more processors are further configured to execute the instructions to cause the apparatus to perform:
dividing the initial quantum layout based on a predetermined basic pattern to obtain a plurality of meshes of the predetermined basic pattern; and
connecting vertices on the boundary of the initial quantum layout in the plurality of meshes into lines to obtain the mesh boundary of the initial quantum layout.

12. The apparatus according to claim 10, wherein the one or more processors are further configured to execute the instructions to cause the apparatus to perform:
determining a mesh boundary including a target number of meshes on the boundary obtained by dividing the initial quantum layout based on a predetermined basic pattern; and
determining the first gradient of the mesh boundary to the geometric parameters of the initial quantum layout based on a change of the target number relative to the geometric parameters of the initial quantum layout.

13. The apparatus according to claim 10, wherein the one or more processors are further configured to execute the instructions to cause the apparatus to perform:
performing electromagnetic simulation on the initial quantum layout of the quantum device, wherein a change of the Hamiltonian parameters of the quantum device is relative to a change of the mesh boundary; and
determining the second gradient of the Hamiltonian parameters of the quantum device to the mesh boundary based on the change of the Hamiltonian parameters of the quantum device relative to the change of the mesh boundary.

14. The apparatus according to claim 10, wherein the one or more processors are further configured to execute the instructions to cause the apparatus to perform:
determining the Hamiltonian parameters of the quantum device with the geometric parameters of the initial quantum layout as variables by taking the mesh boundary as an intermediate transfer quantity in the first gradient and the second gradient; and
determining the target gradient of the Hamiltonian parameters to the geometric parameters of the initial quantum layout.

15. A non-transitory computer readable medium that stores a set of instructions that is executable by one or more processors of an apparatus to cause the apparatus to perform operations comprising:
determining target Hamiltonian parameters of a quantum device;
determining an initial quantum layout of the quantum device and initial geometric parameters of the initial quantum layout;
determining a target gradient of Hamiltonian parameters of the quantum device to geometric parameters of the initial quantum layout; and
adjusting the initial geometric parameters based on the target gradient to have the Hamiltonian parameters of the quantum device be the target Hamiltonian parameters to obtain a target quantum layout.

16. The non-transitory computer readable medium according to claim 15, wherein the operations further comprise:
performing mesh division on the initial quantum layout of the quantum device to obtain a mesh boundary of the initial quantum layout;
determining a first gradient of the mesh boundary to the geometric parameters of the initial quantum layout;
determining a second gradient of the Hamiltonian parameters of the quantum device to the mesh boundary; and
determining the target gradient of the Hamiltonian parameters of the quantum device to the geometric parameters of the initial quantum layout based on the first gradient and the second gradient.

17. The non-transitory computer readable medium according to claim 16, wherein the operations further comprise:
dividing the initial quantum layout based on a predetermined basic pattern to obtain a plurality of meshes of the predetermined basic pattern; and
connecting vertices on the boundary of the initial quantum layout in the plurality of meshes into lines to obtain the mesh boundary of the initial quantum layout.

18. The non-transitory computer readable medium according to claim 16, wherein the operations further comprise:
determining a mesh boundary including a target number of meshes on the boundary obtained by dividing the initial quantum layout based on a predetermined basic pattern; and
determining the first gradient of the mesh boundary to the geometric parameters of the initial quantum layout based on a change of the target number relative to the geometric parameters of the initial quantum layout.

19. The non-transitory computer readable medium according to claim 16, wherein the operations further comprise:
performing electromagnetic simulation on the initial quantum layout of the quantum device, wherein a change of the Hamiltonian parameters of the quantum device is relative to a change of the mesh boundary; and
determining the second gradient of the Hamiltonian parameters of the quantum device to the mesh boundary based on the change of the Hamiltonian parameters of the quantum device relative to the change of the mesh boundary.

20. The non-transitory computer readable medium according to claim 16, wherein the operations further comprise:
determining the Hamiltonian parameters of the quantum device with the geometric parameters of the initial quantum layout as variables by taking the mesh boundary as an intermediate transfer quantity in the first gradient and the second gradient; and
determining the target gradient of the Hamiltonian parameters to the geometric parameters of the initial quantum layout.
